(19) United States
(12) Patent Application Publication
(10) Pub. No.: US 2011/0025941 A1
(43) Pub. Date: Feb. 3, 2011

(54) ACTIVE MATRIX SUBSTRATE, LIQUID CRYSTAL DISPLAY PANEL EQUIPPED WITH THE SAME, AND METHOD OF MANUFACTURING ACTIVE MATRIX SUBSTRATE

(75) Inventor: Hidetoshi Nakagawa, Osaka-shi (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: SHARP KABUSHIKI KAISHA, Osaka-shi, Osaka (JP)

(21) Appl. No.: 12/935,595

(22) PCT Filed: Nov. 25, 2008
(86) PCT No.: PCT/JP2008/003461

§ 371 Date: Sep. 30, 2010

(30) Foreign Application Priority Data
Apr. 28, 2008 (JP) 2008-116695

(51) Int. Cl. G02F 1/1333; H05K 1/11; H05K 13/00

(52) U.S. Cl. 349/56; 174/261; 29/825

(57) ABSTRACT

An active matrix substrate includes: a plurality of first wirings (1a) provided so as to extend parallel to each other; a plurality of second wirings (1b) each provided between adjoining ones of the first wirings (1a) so as to extend parallel to each other; and a third wiring (3c) which is provided so as to cross the first wirings (1a) with an insulating film therebetween, to which the second wirings (1b) are connected via contact holes (11a) formed in the insulating film, and which has a larger width than that of the second wirings (1b). Each of the first wirings (1a) has a multi-line portion (Wa) and a single-line portion (Wb), which are connected together, in a region overlapping the third wiring (3c). The multi-line portions (Wa) and the single-line portions (Wb) of the first wirings (1a) are positioned so as to adjoin each other, the third wiring (3c) has a slit (Sa) provided so as to cross each of the multi-line portions (Wa), and each of the contact holes (11a) is provided between adjoining ones of the single-line portions (Wb).

### TECHNICAL FIELD

The present invention relates to active matrix substrates, liquid crystal display (LCD) panels equipped with the same, and methods of manufacturing an active matrix substrate, and more particularly to techniques of repairing defects in active matrix substrates and LCD panels equipped with the same.

### BACKGROUND ART

LCD panels including active matrix substrates are widely used since the active matrix substrates have, e.g., a thin film transistor (hereinafter referred to as the “TFT”) at every pixel as a minimum unit of an image, and the LCD panels are capable of displaying a high definition moving picture by reliably turning on/off the pixels via the TFTs.

In the LCD panels, the pitches of wirings such as gate lines, source lines, and capacitor lines provided on the active matrix substrates are reduced as the definition of the pixels is increased. This increases the possibility that defects may be produced in the pixels by short-circuits of wirings and/or defective characteristics of the TFTs due to foreign matter called “particles” that adheres to the substrate surface when manufacturing the active matrix substrates. Thus, methods for repairing a pixel having a defect have been proposed (see, e.g., Patent Documents 1-4).

### CITATION LIST

### Patent Document

PATENT DOCUMENT 1: Japanese Published Patent Application No. 2003-114448

PATENT DOCUMENT 2: Japanese Published Patent Application No. 2003-156763

PATENT DOCUMENT 3: Japanese Published Patent Application No. 2003-b 248439

PATENT DOCUMENT 4: Japanese Published Patent Application No. 2004-347891

### SUMMARY OF THE INVENTION

### Technical Problem

FIG. 9 is a partial plan view of a non-display region of a conventional active matrix substrate 120a that is similar to an array substrate of a liquid crystal display disclosed in Patent Document 1, and FIG. 10 is a plan view of the active matrix substrate 120a in which a short-circuit defect has been repaired.

In this active matrix substrate 120a, gate lines 101aa and capacitor lines 101b are alternately provided as first wirings and second wirings so as to extend parallel to each other in a rectangular display region (not shown) for displaying an image. In a non-display region located outside the display region, as shown in FIG. 9, a capacitor main line 103ac is provided as a wide third wiring so as to extend along one side of the display region. As shown in FIG. 9, each capacitor line 101b has a contact portion C at its end, and is connected, at the contact portion C, to the capacitor main line 103c via a contact hole 111a that is formed in a gate insulating film provided so as to cover the gate lines 101aa and the capacitor lines 101b. As shown in FIG. 9, the capacitor main line 103c has a plurality of slits S that extend parallel to each other and perpendicular to the gate lines 101aa.

As shown in FIG. 10, if the capacitor main line 103c and the gate line 101aa are short-circuited together by a particle P in the active matrix substrate 120a, and a short-circuit defect X is produced, a pair of regions L are irradiated with laser light so that a pair of slits S adjoining the short-circuit defect X are connected together at both ends thereof. Thus, the region of the short-circuit defect X is separated from the capacitor main line 103c, whereby the short-circuit defect X between the gate line 101aa (the first wiring) and the capacitor main line 103c (the third wiring) can be repaired. However, since the gap between adjoining ones of the slits S is as large as, e.g., about 45 μm (30 μm to 50 μm) in the active matrix substrate 120a, the length to be cut by the laser radiation is increased. This increases the time it takes to perform the laser cutting operation, or increases the possibility that short-circuit defects may not be repaired successfully, whereby the cycle time for the defect repairing process is increased.

One possible solution to this problem is to form gate lines 101ab (first wirings) each having a multi-line portion in a region overlapping a capacitor main line 103c (a third wiring), as shown in FIGS. 11-12. If a short-circuit defect X is produced in one wiring portion of the multi-line portion of the gate line 101ab, regions (a pair of regions L) located outside the capacitor main line 103c in this wiring portion are irradiated with laser light to separate the wiring portion having the short-circuit defect X from the gate line 101ab, thereby repairing the short-circuit defect X between the gate line 10 lab (the first wiring) and the capacitor main line 103c (the third wiring). FIG. 11 is a partial plan view of a non-display region of a conventional active matrix substrate 120b, and FIG. 12 is a plan view of the active matrix substrate 120b in which the short-circuit defect has been repaired.

In this active matrix substrate 120b, as shown in FIGS. 11-12, the multi-line portion of the gate line 101ab can be easily cut by irradiating the pair of regions L with laser light. Thus, the short-circuit defect X between the gate line 101ab (the first wiring) and the capacitor main line 103c (the third wiring) can be repaired, and the possibility that secondary short-circuit defects may be produced by the laser radiation can be reduced. However, since each gate line 10 lab has a multi-line portion, the gap between the multi-line portion of each gate line 101ab and a contact portion C of an adjoining capacitor line 101b (an adjoining second wiring) is reduced, and thus the gate line 101ab (the first wiring) and the capacitor line 101b (the second wiring) can be short-circuited together by, e.g., a particle adhering to the substrate surface.

The present invention was developed in view of the above problems, and it is an object of the present invention to reduce the possibility of short-circuits between a first wiring and a second wiring and to repair short-circuit defects between the first wiring and a third wiring.

### Solution to the Problem

In order to achieve the above object, according to the present invention, each of first wirings has a multi-line portion and a single-line portion, which are connected together, in a region overlapping a third wiring, the third wiring has a slit provided so as to cross each of the multi-line portions, and each of contact holes for connecting second wirings to the third wiring is provided between adjoining ones of the single-line portions.

Specifically, an active matrix substrate according to the present invention is an active matrix substrate including: a plurality of first wirings provided so as to extend parallel to each other; a plurality of second wirings each provided between adjoining ones of the first wirings so as to extend parallel to each other; and a third wiring which is provided so as to cross the first wirings with an insulating film therebetween, to which the second wirings are connected via contact holes formed in the insulating film, and which has a larger width than that of the second wirings, wherein each of the first wirings has a multi-line portion and a single-line portion, which are connected together, in a region overlapping the third wiring, the multi-line portions and the single-line portions of the first wirings are positioned so as to adjoin each other, the third wiring has a slit provided so as to cross each of the multi-line portions, and each of the contact holes is provided between adjoining ones of the single-line portions.

With the above configuration, each of the first wirings has a multi-line portion and a single-line portion, which are connected together, in the region overlapping the third wiring, and the multi-line portions and the single-line portions of the first wirings are positioned so as to adjoin each other. Thus, the gap between adjoining ones of the single-line portions is larger than that between adjoining ones of the multi-line portions. Since each of the contact holes, which are formed in the insulating film in order to connect the second wirings to the third wiring, is provided between adjoining ones of the single-line portions of the first wirings, the possibility of short-circuits between the first wiring and the second wiring is reduced. If the multi-line portion of the first wiring and the third wiring are short-circuited together by a particle or the like, and a short-circuit defect is produced, the multi-line portion of the first wiring is irradiated with laser light through the slit in the third wiring to separate the portion of the short-circuit defect in the multi-line portion from the first wiring. Thus, the short-circuit defect between the first wiring and the third wiring is repaired. Accordingly, the possibility of short-circuits between the first wiring and the second wiring can be reduced, and short-circuit defects between the first wiring and the third wiring can be repaired.

The first wirings may be gate lines, the second wirings may be capacitor lines, and the third wiring may be a capacitor main line.

With the above configuration, since the first wirings are gate lines, the second wirings are capacitor lines, and the third wiring is a capacitor main line, the functions and advantages of the present invention are specifically obtained. That is, each of the gate lines has a multi-line portion and a single-line portion, which are connected together, in a region overlapping the capacitor main line, and the multi-line portions and the single-line portions of the gate lines are positioned so as to adjoin each other. Thus, the gap between adjoining ones of the single-line portions is larger than that between adjoining ones of the multi-line portions. Since each of the contact holes, which are formed in the insulating film in order to connect the capacitor lines to the capacitor main line, is provided between adjoining ones of the single-line portions of the gate lines, the possibility of short-circuits between the gate line and the capacitor line is reduced. If the multi-line portion of the gate line and the capacitor main line are short-circuited together by a particle or the like, and a short-circuit defect is produced, the multi-line portion of the gate line is irradiated with laser light through the slit in the capacitor main line to separate the region of the short-circuit defect in the multi-line portion from the gate line. Thus, the short-circuit defect between the gate line and the capacitor main line is repaired. Accordingly, the possibility of short-circuits between the gate line and the capacitor line can be reduced, and short-circuit defects between the gate line and the capacitor main line can be repaired.

One ends of the multi-line portions may be exposed from the capacitor main line.

With the above configuration, since one ends of the multi-line portions are exposed from the capacitor main line, the possibility of damage to the capacitor main line due to erroneous laser radiation or the like is reduced, and the one end of the multi-line portion is cut by laser radiation.

The capacitor main line may have a plurality of slits that are formed so as to cross each of the single-line portions.

With the above configuration, the capacitor main line has a plurality of slits that are formed so as to cross each of the single-line portions. Thus, if the capacitor main line and the single-line portion of the gate line are short-circuited together by a particle or the like, and a short-circuit defect is produced, laser radiation is performed so that, of the plurality of slits that are provided in the capacitor main line so as to cross each of the single-line portions, a pair of slits adjoining the short-circuit defect are connected together at both ends thereof. The region of the short-circuit defect is separated from the capacitor main line in this manner.

A display region for displaying an image may be defined, and a non-display region may be defined outside the display region, the capacitor main line may be provided in the non-display region, and the contact holes may be provided on the display region side.

With the above configuration, since the contact holes for connecting the capacitor lines to the capacitor main line are provided on the display region side, the length of the capacitor lines is reduced.

The slit may be separated into portions corresponding to wiring portions of the multi-line portion.

With the above configuration, the slit is separated into the portions corresponding to the wiring portions of the multi-line portion. This reduces the area occupied by the slits in the capacitor main line, and thus reduces an increase in electrical resistance of the capacitor main line.

The slit may be formed along a direction in which the capacitor main line extends.

With the above configuration, the slit is formed along the direction in which the capacitor main line extends. This reduces an increase in electrical resistance of the capacitor main line due to the formation of the slit.

The active matrix substrate having the above configuration is especially effective in an LCD panel including the active matrix substrate, a counter substrate positioned so as to face the active matrix substrate, and a liquid crystal layer interposed therebetween.

A method for manufacturing an active matrix substrate according to the present invention is a method for manufacturing an active matrix substrate including a plurality of first wirings provided so as to extend parallel to each other, a plurality of second wirings each provided between adjoining ones of the first wirings so as to extend parallel to each other, and a third wiring which is provided so as to cross the first wirings with an insulating film therebetween, to which the second wirings are connected via contact holes formed in the insulating film, and which has a larger width than that of the second wirings, where each of the first wirings has a multi-line portion and a single-line portion, which are connected together, in a region overlapping the third wiring, the multi-line portions and the single-line portions of the first wirings are positioned so as to adjoin each other, the third wiring has a slit provided so as to cross each of the multi-line portions, and each of the contact holes is provided between adjoining ones of the single-line portions, the method including: an inspection step of detecting a short-circuit defect between the third wiring and any of the multi-line portions; and a repairing step of irradiating a wiring portion of the multi-line portion having the short-circuit defect detected in the inspection step, with laser light through the slit to separate the wiring portion from the multi-line portion.

According to the above method, each of the first wirings has a multi-line portion and a single-line portion, which are connected together, in the region overlapping the third wiring, and the multi-line portions and the single-line portions of the first wirings are positioned so as to adjoin each other. Thus, the gap between adjoining ones of the single-line portions is larger than that between adjoining ones of the multi-line portions. Since each of the contact holes, which are formed in the insulating film in order to connect the second wirings to the third wiring, is provided between adjoining ones of the single-line portions of the first wirings, the possibility of short-circuits between the first wiring and the second wiring can be reduced. If a short-circuit defect, which is produced by a short-circuit between the multi-line portion of the first wiring and the third wiring due to a particle or the like, is detected in the inspection step, the multi-line portion of the first wiring is irradiated with laser light through the slit of the third wiring in the repairing step to separate the region of the short-circuit defect in the multi-line portion from the first wiring. Thus, the short-circuit defect between the first wiring and the third wiring is repaired. Accordingly, the possibility of short-circuits between the first wiring and the second wiring can be reduced, and short-circuit defects between the first wiring and the third wiring can be repaired.

### ADVANTAGES OF THE INVENTION

According to the present invention, each of the first wirings has a multi-line portion and a single-line portion, which are connected together, in the region overlapping the third wiring, the third wiring has a slit provided so as to cross each of the multi-line portions, and each of the contact holes for connecting the second wirings to the third wiring is provided between adjoining ones of the single-line portions. Thus, the possibility of short-circuits between the first wiring and the second wiring can be reduced, and a short-circuit defect between the first wiring and the third wiring can be repaired.

### BRIEF DESCRIPTION OF THE DRAWINGS

FIG. 1 is a plan view of an LCD panel 50 according to a first embodiment.

FIG. 2 is a plan view of a pixel in an active matrix substrate 20a of the LCD panel 50.

FIG. 3 is a cross-sectional view of the active matrix substrate 20a and the LCD panel 50 including the same, taken along line III-III in FIG. 2.

FIG. 4 is an enlarged plan view of the active matrix substrate 20a in a region A in FIG. 1.

FIG. 5 is a plan view corresponding to FIG. 4, showing the active matrix substrate 20a in which a defect has been repaired.

FIG. 6 is a plan view corresponding to FIG. 4, showing an active matrix substrate 20b according to a second embodiment.

FIG. 7 is a plan view corresponding to FIG. 4, showing an active matrix substrate 20c according to a third embodiment.

FIG. 8 is a plan view corresponding to FIG. 4, showing an active matrix substrate 20d according to a fourth embodiment.

FIG. 9 is a partial plan view of a non-display region of a conventional active matrix substrate 120a.

FIG. 10 is a plan view of the active matrix substrate 120a in which a short-circuit defect has been repaired.

FIG. 11 is a partial plan view of a non-display region of a conventional active matrix substrate 120b.

FIG. 12 is a plan view of the active matrix substrate 120b in which a short-circuit defect has been repaired.

### DESCRIPTION OF REFERENCE CHARACTERS

D Display Region
N Non-Display Region
Sa, Sb Slit
W Wiring Portion
Wa Multi-Line Portion
Wb Single-Line Portion
X Short-Circuit Defect
1a Gate Line (First Wiring)
1b Capacitor Line (Second Wiring)
3c Capacitor Main Line (Third Wiring)
11 Gate Insulating Film
11a Contact Hole
20a-20d Active Matrix Substrate
30 Counter Substrate
40 Liquid Crystal Layer (Display Medium Layer)
50 LCD Panel

### DESCRIPTION OF EMBODIMENTS

Embodiments of the present invention will be described in detail below with reference to the accompanying drawings. Note that the present invention is not limited to the following embodiments.

### First Embodiment

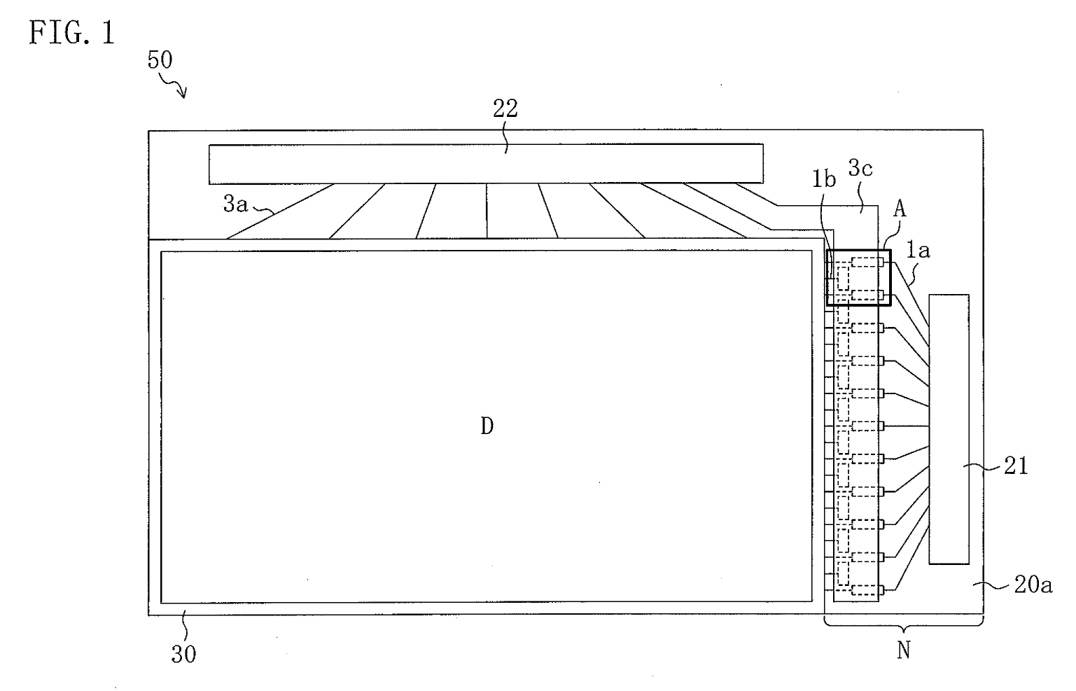

FIGS. 1-5 show a first embodiment of an active matrix substrate, an LCD panel including the same, and a manufacturing method of the active matrix substrate according to the present invention.

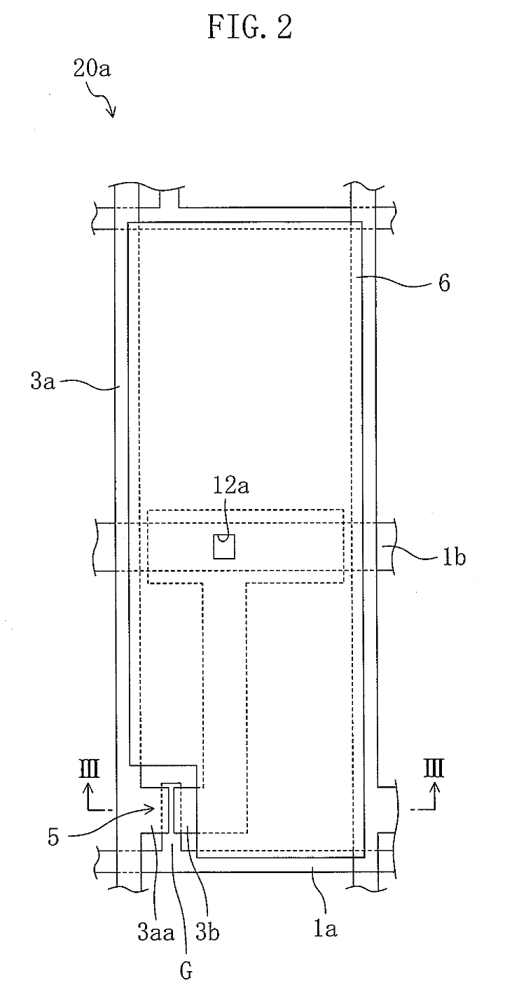

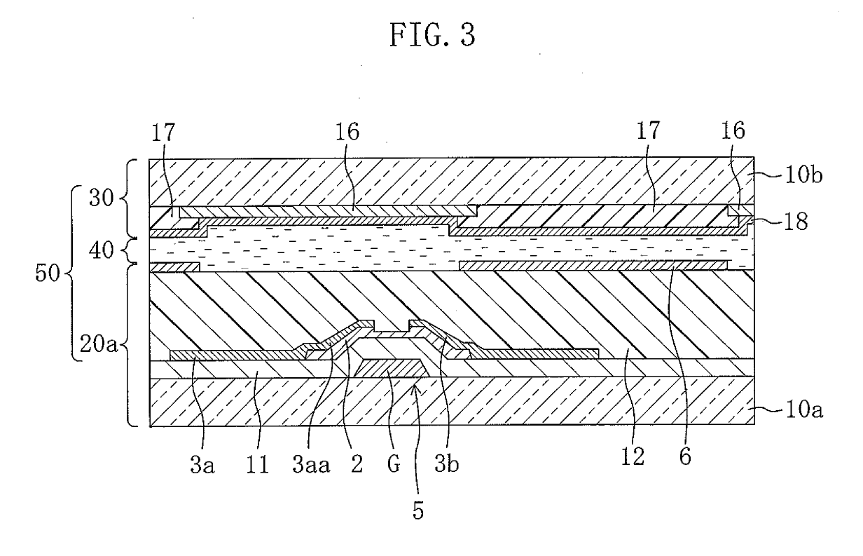

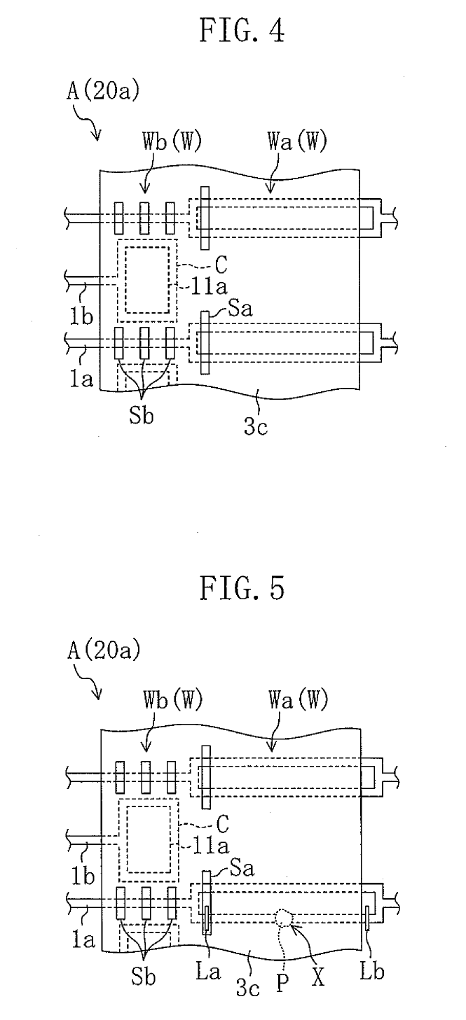

Specifically, FIG. 1 is a plan view of an LCD panel 50 of the present embodiment, and FIG. 2 is a plan view of a pixel in an active matrix substrate 20a of the LCD panel 50. FIG. 3 is a cross-sectional view of the active matrix substrate 20a and the LCD panel 50 including the same, taken along line III-III in FIG. 2, and FIG. 4 is an enlarged plan view of the active matrix substrate 20a in a region A in FIG. 1.

As shown in FIGS. 1 and 3, the LCD panel 50 includes: the active matrix substrate 20a and a counter substrate 30, which are positioned so as to face each other; a liquid crystal layer 40 provided as a display medium layer between the active matrix substrate 20a and the counter substrate 30; and a sealant (not shown) for bonding the active matrix substrate 20a and the counter substrate 30 together and enclosing the liquid crystal layer 40.

As shown in FIG. 1, in the LCD panel 50, a display region D for displaying an image is defined in a region where the active matrix substrate 20a overlaps the counter substrate 30a, and a non-display region N is defined in a region outside the display region D, that is, a region of the active matrix substrate 20a, which is exposed from the counter substrate 30. A plurality of pixels, which are minimum units of an image and correspond to pixel electrodes 6 described below, are arranged in a matrix pattern in the display region D. As shown in FIG. 1, a gate driver 21 and a source driver 22 are provided in the non-display region N.

As shown in FIGS. 2-3, the active matrix substrate 20a includes in the display region D: a plurality of gate lines 1a provided as first wirings on an insulating substrate 10a so as to extend parallel to each other; a plurality of capacitor lines 1b each provided as a second wiring between adjoining ones of the gate lines 1a so as to extend parallel to each other; a gate insulating film 11 provided so as to cover the gate lines 1a and the capacitor lines 1b; a plurality of source lines 3a provided on the gate insulating film 11 so as to extend parallel to each other in a direction perpendicular to the gate lines 1a; a plurality of TFTs 5 provided at the intersections of the gate lines 1a and the source lines 3a; an interlayer insulating film 12 provided so as to cover the TFTs 5 and the source lines 3a; a plurality of pixel electrodes 6 provided in a matrix pattern on the interlayer insulating film 12; and an alignment film (not shown) provided so as to cover the pixel electrodes 6.

As shown in FIGS. 2-3, each TFT 5 includes: a gate electrode G that is a laterally protruding portion of the gate line 1a; the gate insulating film 11 provided so as to cover the gate electrode G; an island-shaped semiconductor layer 2 provided at a position corresponding to the gate electrode G on the gate insulating film 11; and a source electrode 3aa and a drain electrode 3b provided so as to face each other on the semiconductor layer 2. As shown in FIG. 2, the source electrode 3aa is a laterally protruding portion of the source line 3a. As shown in FIG. 2, the drain electrode 3b is extended to a region that overlaps the capacitor line 1b, thereby forming an auxiliary capacitor. The drain electrode 3b is connected to the pixel electrode 6 via a contact hole 12a formed in the interlayer insulating film 12 over the capacitor line 1b.

As shown in FIG. 1, in the non-display region N of the active matrix substrate 20a, the gate lines 1a extend so as to be connected to the gate driver 21, and the source lines 3a extend so as to be connected to the source driver 22. As shown in FIG. 1, in the non-display region N of the active matrix substrate 20a, a capacitor main line 3c is provided as a third wiring so as to extend along the right side of the display region D from the source driver 22.

As shown in FIG. 4, contact portions C of the capacitor lines 1b are connected to the capacitor main line 3c via contact holes 11a formed in the gate insulating film (not shown). Note that the wide contact portions C (e.g., about 100 μm×200 μm) are provided at the ends of the capacitor lines 1b. The width of the capacitor main line 3c is, e.g., about 500 μm to 700 μm. The width of the gate lines 1a is, e.g., about 15 μm in multi-line portions Wa described below, and about 30 μm in single-line portions Wb described below. The width of the capacitor lines 1b is, e.g., about 20 μm.

As shown in (FIG. 1 and) FIG. 4, each gate line 1a has a multi-line portion Wa and a single-line portion Wb, which are connected together, in a region overlapping the capacitor main line 3c. Note that the gap between wiring portions W of each multi-line portion Wa is about 50 μm. As shown in FIG. 4, the multi-line portions Wa and the single-line portions Wb of the gate lines 1a are positioned so as to adjoin each other. As shown in FIG. 4, the contact portion C and the contact hole 11a for connecting the capacitor main line 3c and the capacitor line 1b are provided between adjoining ones of the single-line portions Wb on the display region D side. Note that the gap between adjoining ones of the single-line portions Wb is, e.g., about 300 μm, which is larger than the gap between adjoining ones of the multi-line portions Wa (e.g., about 220 μm). As shown in FIG. 4, one end (on the side that is not connected to the single-line portion Wb) of each multi-line portion Wa is exposed from the capacitor main line 3c.

As shown in FIG. 4, the capacitor main line 3c has a slit Sa extending perpendicular to (wiring portions W of) each multi-line portion Wa, and a plurality of slits Sb extending perpendicular to (a wiring portion W of) each single-line portion Wb. That is, the slits Sa and the slits Sb are provided along the direction in which the capacitor main line 3c extends. The size of the slits Sa is, e.g., about 8 μm to 100 μm, and the size of the slits Sb is, e.g., about 8 μm×50 μm. The gap between adjoining ones of the slits Sb is, e.g., about 45 μm.

As shown in FIG. 3, the counter substrate 30 includes: an insulating substrate 10b; a black matrix 16 provided in a grid pattern on the insulating substrate 10b; a color filter 17 including red, green, and blue layers provided between the grid lines of the black matrix 16; a common electrode 18 provided so as to cover the black matrix 16 and the color filter 17; columnar photo spacers (not shown) provided on the common electrode 18; and an alignment film (not shown) provided so as to cover the common electrode 18.

The liquid crystal layer 40 is made of a nematic liquid crystal material having electro-optic characteristics, or the like.

In the LCD panel 50 having the above configuration, when the TFT 5 of each pixel is turned on in response to a gate signal sent from the gate driver 21 to the gate electrode G via the gate line 1a, a source signal is sent from the source driver 22 to the source electrode 3aa via the source line 3a, and a predetermined amount of charge is written to the pixel electrode 6 via the semiconductor layer 2 and the drain electrode 3b. This produces a potential difference between the pixel electrode 6 of the active matrix substrate 20a and the common electrode 18 of the counter substrate 30, whereby a predetermined voltage is applied to the liquid crystal layer 40. The LCD panel 50 displays an image by adjusting the light transmittance of the liquid crystal layer 40 by changing the alignment state of the liquid crystal layer 40 according to the magnitude of the applied voltage to the liquid crystal layer 40.

An example of a manufacturing method of the active matrix substrate 20a and the LCD panel 50 and a defect repairing method according to the present embodiment will be described below. The manufacturing method of the present embodiment includes an active matrix substrate fabricating step, a counter substrate fabricating step, a sealant applying step, a liquid crystal dropping step, a bonding step, an inspection step, and a repairing step.

[Active Matrix Substrate Fabricating Step]

First, films such as a titanium film, an aluminum film, and a titanium film are sequentially formed by a sputtering method on the entire surface of an insulating substrate 10a such as a glass substrate. The films are then patterned by photolithography to form gate lines 1a, gate electrodes G, and capacitor lines 1b with a thickness of about 4,000 Å.

Next, a silicon nitride film or the like is formed by a plasma chemical vapor deposition (CVD) method over the entire substrate having the gate lines 1a, the gate electrodes G, and the capacitor lines 1b formed thereon to form a gate insulating film 11 with a thickness of about 4,000 Å.

Then, an intrinsic amorphous silicon film and a phosphorus-doped n+ amorphous silicon film are sequentially formed by a plasma CVD method over the entire substrate having the gate insulating film 11 formed thereon. The intrinsic amorphous silicon film and the phosphorus-doped n+ amorphous silicon film are then patterned by photolithography into an island shape on the gate electrodes G to form a semiconductor formation layer in which the intrinsic amorphous silicon layer having a thickness of about 2,000 Å and the n+ amorphous silicon layer having a thickness of about 500 Å are laminated together.

Thereafter, films such as an aluminum film and a titanium film are formed by a sputtering method over the entire substrate having the semiconductor formation layer formed thereon. The films are then patterned by photolithography to form source lines 3a, source electrodes 3aa, drain electrodes 3b, and a capacitor main line 3c with a thickness of about 2,000 Å.

Then, by using the source electrodes 3aa and the drain electrodes 3b as a mask, the n+ amorphous silicon layer of the semiconductor formation layer is etched to pattern channel portions, thereby forming semiconductor layers 2 and TFTs 5 having the same.

For example, an acrylic photosensitive resin is then applied by a spin coating method to the entire substrate having the TFTs 5 formed thereon. The applied photosensitive resin is exposed via a photomask and developed to form an interlayer insulating film 12 having contact holes 12a patterned on the drain electrodes 3b, and having a thickness of about 2 μm to 3 μm.

Subsequently, an indium tin oxide (ITO) film is formed by a sputtering method over the entire substrate having the interlayer insulating film 12 formed thereon. The ITO film is then patterned by photolithography to form pixel electrodes 6 with a thickness of about 1,000 Å.

Finally, a polyimide resin is applied by a printing method to the entire substrate having the pixel electrodes 6 formed thereon. The polyimide resin is then rubbed to form an alignment film with a thickness of about 1,000 Å.

The active matrix substrate 20a can be fabricated in this manner.

[Counter Substrate Fabricating Step]

First, for example, a negative acrylic photosensitive resin having fine particles such as carbon dispersed therein is applied by a spin coating method to the entire surface of an insulating substrate 10b such as a glass substrate. The applied photosensitive resin is exposed via a photomask and developed to form a black matrix 16 with a thickness of about 1.5 μm.

Next, for example, a red, green, or blue-colored negative acrylic photosensitive resin is applied to the substrate having the black matrix 16 formed thereon. The applied photosensitive resin is exposed via a photomask and developed to pattern a colored layer of a selected color (e.g., a red layer) with a thickness of about 2.0 μm. Similar steps are repeated for the remaining two colors to form colored layers of the two colors (e.g., a green layer and a blue layer) with a thickness of about 2.0 μm. A color filter 17 is formed in this manner.

For example, an ITO film is then formed by a sputtering method over the substrate having the color filter 17 formed thereon to form a common electrode 18 with a thickness of about 1,500 Å.

Thereafter, a positive phenol novolac photosensitive resin is applied by a spin coating method to the entire substrate having the common electrode 18 formed thereon. The applied photosensitive resin is exposed via a photomask and developed to form photo spacers with a thickness of about 4 μm.

Finally, a polyimide resin is applied by a printing method to the entire substrate having the photo spacers formed thereon. The polyimide resin is then rubbed to form an alignment film with a thickness of about 1,000 Å.

The counter substrate 30 can be fabricated in this manner.

[Sealant Applying Step]

For example, by using a dispenser, a sealant, which is made of an ultraviolet (UV) curable, thermosetting resin or the like, is applied (written or painted) in a frame shape to the counter substrate 30 fabricated by the counter substrate fabricating step.

[Liquid Crystal Dropping Step]

A liquid crystal material is dropped onto a region inside the sealant on the counter substrate 30 having the sealant applied thereto in the sealant applying step.

[Bonding Step]

First, the counter substrate 30 having the liquid crystal material dropped thereon in the liquid crystal dropping step is bonded under reduced pressure with the active matrix substrate 20a fabricated in the active matrix substrate fabricating step. Then, the bonded body of the counter substrate 30 and the active matrix substrate 20a is exposed to atmospheric pressure to press the surfaces of the bonded body.

Then, the sealant held in the bonded body is irradiated with UV light, and the bonded body is heated to cure the sealant.

The LCD panel 50 (which has not been inspected) can be manufactured in this manner. Thereafter, each LCD panel 50 manufactured is subjected to the inspection step described below, and if any pixel having a short-circuit between the capacitor main line 3c and the gate line 1a is detected, the detected defect is repaired by the repairing step described below. Note that the gate driver 21 and the source driver 22 are placed in normal LCD panels in which no defects such as short-circuit defects are detected in the inspection step, and LCD panels in which short-circuit defects have been repaired in the repairing step. FIG. 5 is a plan view corresponding to FIG. 4, showing the active matrix substrate 20a in which a defect has been repaired.

[Inspection Step]

In the LCD panel 50 manufactured as described above, a gate inspection signal is applied to the gate lines 1a to turn on all the TFTs 5, and a source inspection signal is applied to the source lines 3a to apply the source inspection signal to the pixel electrodes 6 via the TFTs 5. The gate inspection signal is a signal of a bias voltage of −10 V and a pulse voltage of +15 V having a period of 16.7 msec and a pulse width of 50 μsec, and the source inspection signal is a signal having a potential of ±2 V with its polarity inverted every 16.7 msec. At the same time, a common electrode inspection signal having a direct current (DC) potential of −1 V is applied to the common electrode 18 to apply a voltage to the liquid crystal layer 40 between each pixel electrode 16 and the common electrode 18, whereby the pixels formed by the pixel electrodes 6 operate. In, e.g., a normally black mode LCD panel 50 (an LCD panel that provides black display when no voltage is applied), the display screen switches from black display to white display at this time. If the capacitor main line 3c and the gate line 1a are short-circuited together by a particle P (see FIG. 5) or the like, on/off control of the corresponding TFTs 5 does not work, causing unevenness of display along the gate line in the display region D. Thus, a short-circuit defect X is defected by visually verifying the capacitor main line 3c from the substrate side through a microscope or the like.

[Repairing Step]

As shown in FIG. 5, in the wiring portions W of the multi-line portion Wa of the gate line 1a having the detected short-circuit defect X, a region La is irradiated with, e.g., laser light oscillated from a yttrium aluminum garnet (YAG) laser through a slit Sa of the capacitor main line 3c, and a region Lb is also irradiated with the laser light to separate the region of the short-circuit defect X in the multi-line portion Wa from the gate line 1a. The short-circuit between the capacitor main line 3c and the gate line 1a can be eliminated in this manner.

As described above, according to the active matrix substrate 20a, the LCD panel 50 including the same, and the manufacturing method of the active matrix substrate 20a and the LCD panel 50 of the present embodiment, each gate line 1a has the multi-line portion Wa and the single-line portion Wb, which are connected together, in a region overlapping the capacitor main line 3c, and the multi-line portions Wa and the single-line portions Wb of the gate lines 1a are positioned so as to adjoin each other. Thus, the gap between adjoining ones of the single-line portions Wb is larger than that between adjoining ones of the multi-line portions Wa. Each of the contact holes 11a, which are formed in the gate insulating film 11 in order to connect the capacitor lines 1b to the capacitor main line 3c, is provided between adjoining ones of the single-line portions Wb of the gate lines 1a. This can reduce the possibility of short-circuits between the gate line 1a and the capacitor line 1b. Moreover, if a short-circuit defect X, which is produced by a short-circuit between the capacitor main line 3c and the multi-line portion Wa of the gate line 1a by a particle P, is detected in the inspection step, the multi-line portion Wa of the gate line 1a is irradiated with laser light through the slit Sa of the capacitor main line 3c in the repairing step to separate the region of the short-circuit defect X in the multi-line portion Wa from the gate line 1a. Thus, the short-circuit defect between the gate line 1a and the capacitor main line 3c can be repaired. Accordingly, the possibility of short-circuits between the gate line and the capacitor line can be reduced, and short-circuit defects between the gate line and the capacitor main line can be repaired.

According to the present embodiment, since one end of the multi-line portion Wa is exposed from the capacitor main line 3c, the possibility of damage to the capacitor main line 3c due to erroneous laser radiation or the like can be reduced, and one end of the multi-line portion Wa can be cut by laser radiation.

According to the present embodiment, the plurality of slits Sb are formed in the capacitor main line 3c so as to cross the single-line portion Wb. Thus, if the capacitor main line 3c and the single-line portion Wb of the gate line 1a are short-circuited together by a particle or the like, and a short-circuit defect is produced, laser radiation is performed so that, of the plurality of slits Sb provided in the capacitor main line 3c, a pair of slits Sb adjoining the short-circuit defect are connected together at both ends thereof. Thus, the region of the short-circuit defect can be separated from the capacitor main line 3c, whereby the short-circuit between the capacitor main line 3c and the single-line portion Wb of the gate line 1a can be eliminated.

According to the present embodiment, since the contact holes 11a for connecting the capacitor lines 1b to the capacitor main line 3c are provided on the display region D side, the capacitor lines 1b can be designed to have a short length.

According to the present embodiment, the slits Sa, Sb are formed along the direction in which the capacitor main line 3c extends. This can reduce an increase in electrical resistance of the capacitor main line 3c due to the formation of the slits Sa, Sb.

### Second Embodiment

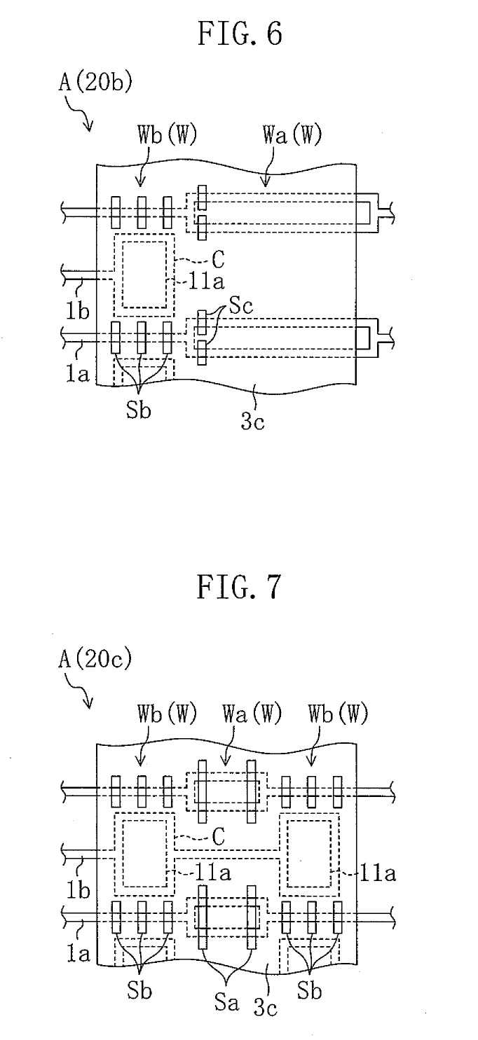

FIG. 6 is a plan view corresponding to FIG. 4, showing an active matrix substrate 20b of the present embodiment. Note that in the following embodiments, the same portions as those of FIGS. 1-5 are denoted by the same reference characters, and detailed description thereof will be omitted.

As shown in FIG. 4, in the active matrix substrate 20a of the first embodiment, the slit Sa for cutting the multi-line portion Wa of the gate line 1a crosses both wiring portions W of the multi-line portion Wa. However, in the active matrix substrate 20b of the present embodiment, as shown in FIG. 6, a slit Sc for cutting the multi-line portion Wa of the gate line 1a is separated into portions corresponding to the wiring portions W of the multi-line portion Wa so that the separated slits Sc cross the wiring portions W of the multi-line portion Wa, respectively.

In the active matrix substrate 20b, an LCD panel including the same, and a manufacturing method of the active matrix substrate 20b and the LCD panel according to the present embodiment, the slits Sc are separated from each other so as to correspond to the wiring portions W. This reduces the area that is occupied by the slits Sc in the capacitor main line 3c, and thus can reduce an increase in electrical resistance of the capacitor main line 3c. Moreover, as in the first embodiment, the possibility of short-circuits between the gate line and the capacitor line can be reduced, and short-circuit defects between the gate line and the capacitor main line can be repaired.

### Third Embodiment

FIG. 7 is a plan view corresponding to FIG. 4, showing an active matrix substrate 20c of the present embodiment.

In the active matrix substrates 20a, 20b of the first and second embodiments, as shown in FIGS. 4 and 6, one contact hole 11a is formed for each capacitor line 1b, and the contact holes 11a are provided on the display region D side of the capacitor main line 3c. In the active matrix substrate 20c of the present embodiment, however, as shown in FIG. 7, contact holes 11a are provided not only on the display region D side of the capacitor main line 3c, but also on the side opposite to the display region D of the capacitor main line 3c.

As in the first and second embodiments, in the active matrix substrate 20c, an LCD panel including the same, and a manufacturing method of the active matrix substrate 20c and the LCD panel according to the present embodiment, the possibility of short-circuits between the gate line and the capacitor line can be reduced, and short-circuit defects between the gate line and the capacitor main line can be repaired.

### Fourth Embodiment

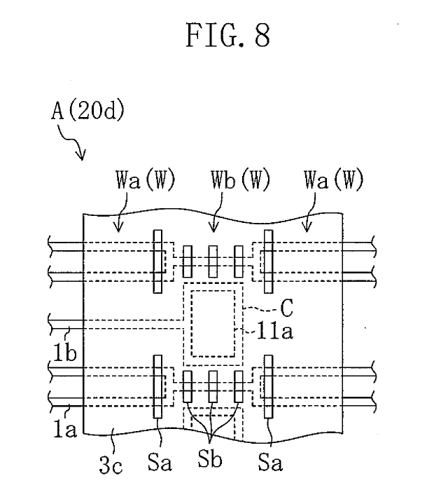

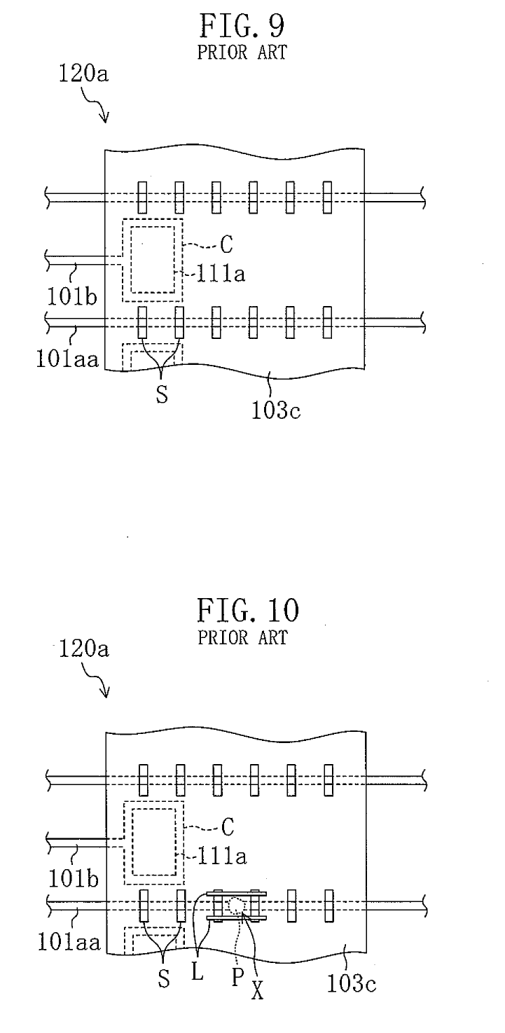

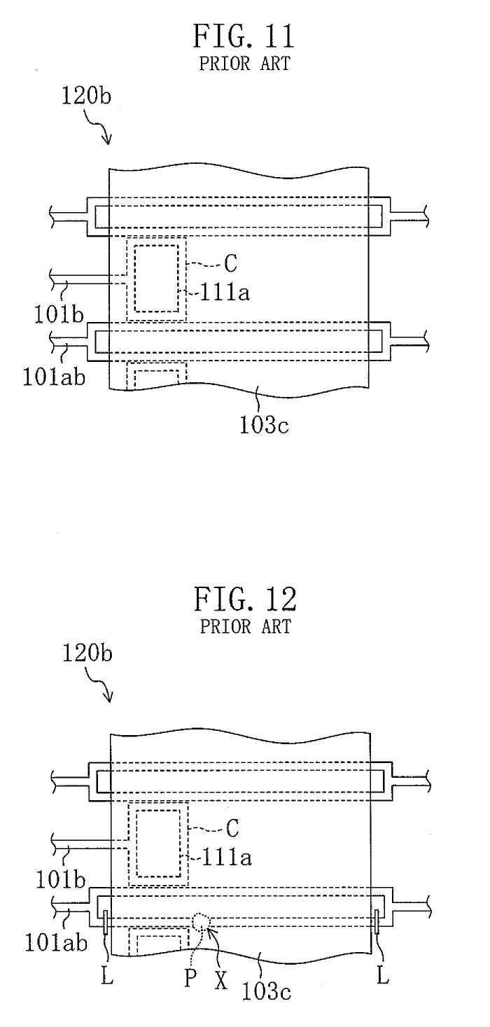

FIG. 8 is a plan view corresponding to FIG. 4, showing an active matrix substrate 20d of the present embodiment.

In the active matrix substrates 20a, 20b, 20c of the first, second, and third embodiments, as shown in FIGS. 4, 6, and 7, the contact holes 11a are provided in an end or ends in the width direction of the capacitor main line 3c. In the active matrix substrate 20d of the present embodiment, however, as shown in FIG. 8, contact holes 11a are provided in the middle in the width direction of the capacitor main line 3c.

As in the first, second, and third embodiments, in the active matrix substrate 20d, an LCD panel including the same, and a manufacturing method of the active matrix substrate 20d and the LCD panel according to the present embodiment, the possibility of short-circuits between the gate line and the capacitor line can be reduced, and short-circuit defects between the gate line and the capacitor main line can be repaired.

Note that in the present invention, the positions of the contact holes 11a in the capacitor main line 3c can be changed as appropriate as shown in the above embodiments. Thus, the positions of the contact holes 11a on the active matrix substrate can be designed so that the contact holes 11a do not overlap the photo spacers provided over the counter substrate 30.

In the manufacturing methods shown in the above embodiments, the repairing step is performed after the inspection step of carrying out a dynamic operation inspection of the LCD panel formed by bonding the active matrix substrate and the counter substrate. However, the present invention is also applicable to manufacturing methods in which the repairing step is performed after the inspection step of performing a continuity inspection or the like on the active matrix substrate.

### INDUSTRIAL APPLICABILITY

As described above, according to the present invention, the possibility of short-circuits between the gate line and the capacitor line can be reduced, and short-circuit defects between the gate line and the capacitor main line can be repaired. Thus, the present invention is useful for active matrix substrates and LCD panels including the same, for which higher definition of pixels is desired.

1. An active matrix substrate, comprising:
a plurality of first wirings provided so as to extend parallel to each other;
a plurality of second wirings each provided between adjoining ones of the first wirings so as to extend parallel to each other; and
a third wiring which is provided so as to cross the first wirings with an insulating film therebetween, to which the second wirings are connected via contact holes formed in the insulating film, and which has a larger width than that of the second wirings, wherein
each of the first wirings has a multi-line portion and a single-line portion, which are connected together, in a region overlapping the third wiring,
the multi-line portions and the single-line portions of the first wirings are positioned so as to adjoin each other,
the third wiring has a slit provided so as to cross each of the multi-line portions, and
each of the contact holes is provided between adjoining ones of the single-line portions.

2. The active matrix substrate of claim 1, wherein
the first wirings are gate lines,
the second wirings are capacitor lines, and
the third wiring is a capacitor main line.

3. The active matrix substrate of claim 2, wherein
one ends of the multi-line portions are exposed from the capacitor main line.

4. The active matrix substrate of claim 2, wherein
the capacitor main line has a plurality of slits that are formed so as to cross each of the single-line portions.

5. The active matrix substrate of claim 2, wherein
a display region for displaying an image is defined, and a non-display region is defined outside the display region,
the capacitor main line is provided in the non-display region, and
the contact holes are provided on the display region side.

6. The active matrix substrate of claim 2, wherein
the slit is separated into portions corresponding to wiring portions of the multi-line portion.

7. The active matrix substrate of claim 2, wherein
the slit is formed along a direction in which the capacitor main line extends.

8. An LCD panel, comprising:
the active matrix substrate of claim 1;
a counter substrate positioned so as to face the active matrix substrate; and
a liquid crystal layer interposed therebetween.

9. A method for manufacturing an active matrix substrate including
a plurality of first wirings provided so as to extend parallel to each other,
a plurality of second wirings each provided between adjoining ones of the first wirings so as to extend parallel to each other, and
a third wiring which is provided so as to cross the first wirings with an insulating film therebetween, to which the second wirings are connected via contact holes formed in the insulating film, and which has a larger width than that of the second wirings, where
each of the first wirings has a multi-line portion and a single-line portion, which are connected together, in a region overlapping the third wiring,
the multi-line portions and the single-line portions of the first wirings are positioned so as to adjoin each other,
the third wiring has a slit provided so as to cross each of the multi-line portions, and
each of the contact holes is provided between adjoining ones of the single-line portions, the method comprising:
an inspection step of detecting a short-circuit defect between the third wiring and any of the multi-line portions; and
a repairing step of irradiating a wiring portion of the multi-line portion having the short-circuit defect detected in the inspection step, with laser light through the slit to separate the wiring portion from the multi-line portion.
